(19) United States
(12) Patent Application Publication
(10) Pub. No.: US 2025/0330159 A1
(43) Pub. Date: Oct. 23, 2025

(54) PHASE ERROR DETECTION AND CORRECTION

(71) Applicant: Micron Technology, Inc., Boise, ID (US)

(72) Inventor: Gyutae Park, Boise, ID (US)

(21) Appl. No.: 19/046,374

(22) Filed: Feb. 5, 2025

Related U.S. Application Data
(60) Provisional application No. 63/635,988, filed on Apr. 18, 2024.

(51) Int. Cl. H03K 5/01; H03K 5/00

(52) U.S. Cl. CPC H03K 5/01; H03K 2005/00286

(57) ABSTRACT

Methods, systems, and devices for phase error detection and correction are described. A system may implement phase detection circuits configured to receive one or more respective clock signals from one or more phase adjustor circuits. The phase detection circuits may perform a comparison between the respective clock signals. The phase detector circuits may utilize multiple sets of transistors to compare the clock signals. The multiple sets of transistors may be coupled between various current sources and outputs of the circuit. The transistors may be operable based on multiple clock signals received from the phase adjustor circuits. The phase detector circuit may compare various voltage levels at respective outputs to detect one or more phase errors and output one or more phase errors to the phase adjustor circuits.

### CROSS REFERENCE

The present Application for Patent claims priority to U.S. Patent Application No. 63/635,988 by Park, entitled “PHASE ERROR DETECTION AND CORRECTION,” filed Apr. 18, 2024, which is assigned to the assignee hereof, and which is expressly incorporated by reference in its entirety herein.

### TECHNICAL FIELD

The following relates to one or more systems for memory, including phase error detection and correction.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports phase error detection and correction in accordance with examples as disclosed herein.

FIG. 2 shows an example of a system that supports phase error detection and correction in accordance with examples as disclosed herein.

FIG. 3 shows an example of a circuit that supports phase error detection and correction in accordance with examples as disclosed herein.

FIG. 4 shows an example of a circuit that supports phase error detection and correction in accordance with examples as disclosed herein.

### DETAILED DESCRIPTION

Some systems (e.g., a semiconductor system, a memory system) may utilize various timing signals (e.g., clock signals) to operate one or more components of the system (e.g., a data component, a memory device, a storage component). In some cases, the timing signals may be associated with various phase shifts relative to one another. Some of the phase-shifted signals may also be associated with phase errors (e.g., an error relative to a target phase shift value). Such phase errors may cause the system to be inoperable or may otherwise comprise a functionality of the system. Accordingly, systems may be configured with phase error detection and phase error correction circuits (e.g., four phase error detection and correction) to mitigate such adverse effects. However, some phase error detection circuits may be associated with relatively complex logic (e.g., complex circuitry). For instance, some phase error detections circuits may occupy a relatively large area (e.g., of a semiconductor die) and may consume a relatively high levels of energy (e.g., power, electrical current). Such adverse effects may decrease a sustainability of such systems (e.g., based on the large die area usage) and may also increase power consumption.

In accordance with one or more techniques described herein, phase detection circuits may be implemented with circuitry that decreases architecture complexity, increases power efficiency, and achieves other benefits. In some examples, a system may include various phase detection circuits that are configured to receive one or more respective clock signals from one or more phase adjustor circuits. In some examples, the phase detector circuits may utilize multiple sets of transistors (e.g., P-type transistors, N-type transistors) to compare the clock signals. The multiple sets of transistors (e.g., the terminals of the transistors) may be coupled between various current sources and outputs of the circuit. The transistors may be operable (e.g., switched “on” or “off”) based on multiple clock signals (e.g., the clock signals themselves, inversions of the clock signals, generated signals based on the clock signals) received from the phase adjustor circuitry (e.g., and applied to respective gates of the transistors). Based on the current sources, the clock signals, and the transistor circuitry, the phase detector circuit may operate based on relatively fewer input clock signals. Additionally, the transistor circuitry may be configured to compensate for a timing difference that is induced based on reducing a quantity of input clock signals. The phase detector circuit may compare various voltage levels at respective outputs to detect (e.g., identity, determine) one or more phase errors and may generate (e.g., output, feedback, transmit) one or more phase errors to the phase adjustor circuits. Accordingly, such phase error detection circuitry may reduce area (e.g., die area), reduce processing complexity, and reduce power consumption of the system.

In addition to applicability in memory systems as described herein, techniques for phase error detection and correction may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by reducing materials used in production of electronic devices (e.g., based on reduced area occupied by phase detection circuitry) and reducing power consumption of electronic devices, which may result in lowered production emissions, reduce electronic waste, and improve energy efficiency of electronic devices, among other benefits.

Features of the disclosure are illustrated and described in the context of systems. Features of the disclosure are further illustrated and described in the context of circuits and timing diagrams.

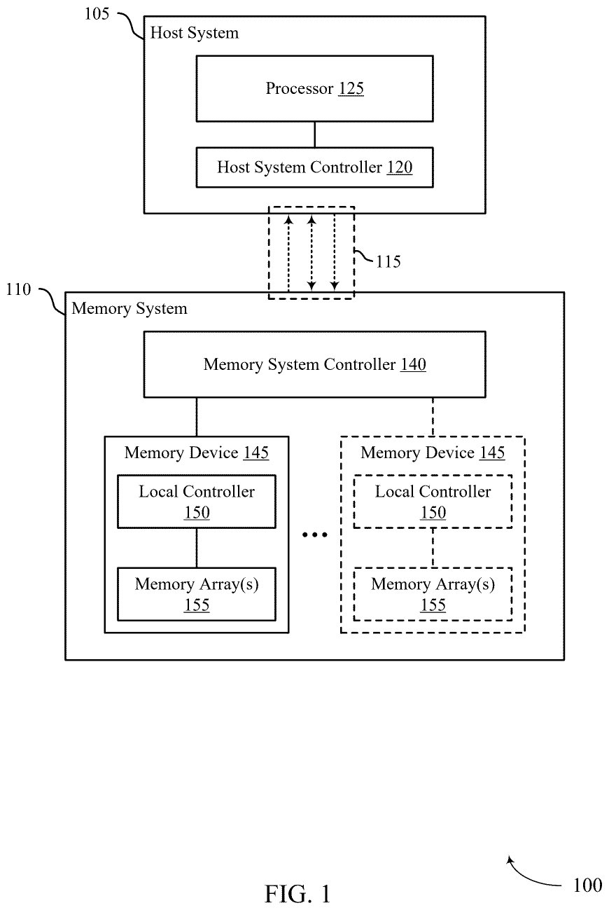

FIG. 1 illustrates an example of a system 100 that supports phase error detection and correction in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, one or more processing components) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory chips) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not- or (NOR) memory cells, and not- and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

A command/address channel (e.g., a CA channel) may be operable to communicate commands between the host system 105 and the memory system 110, including control information associated with the commands (e.g., address information, configuration information). Commands carried by a command/address channel may include a write command with an address for data to be written to the memory system 110 or a read command with an address of data to be read from the memory system 110.

A clock signal channel may be operable to communicate one or more clock signals between the host system 105 and the memory system 110. Clock signals may oscillate between a high state and a low state, and may support coordination (e.g., in time) between operations of the host system 105 and the memory system 110. In some examples, a clock signal may provide a timing reference for operations of the memory system 110. A clock signal may be referred to as a control clock signal, a command clock signal, or a system clock signal. A system clock signal may be generated by a system clock, which may include one or more hardware components (e.g., oscillators, crystals, logic gates, transistors).

A data channel (e.g., a DQ channel) may be operable to communicate (e.g., bidirectionally) information (e.g., data, control information) between the host system 105 and the memory system 110. For example, a data channel may communicate information from the host system 105 to be written to the memory system 110, or information read from the memory system 110 to the host system 105. In some examples, channels 115 may include one or more error detection code (EDC) channels. An EDC channel may be operable to communicate error detection signals, such as checksums or parity bits, which may accompany information conveyed over a data channel.

In some cases, the host system 105, the memory system 110, or other aspects of the system 100 may utilize various timing signals (e.g., clock signals) to operate one or more components (e.g., a processor 125, a host system controller 120, a memory system controller 140, a memory device 145, to access one or more memory arrays 155). In some cases, the timing signals may be associated with various phase shifts relative to one another. Some of the phase-shifted signals may also be associated with phase errors (e.g., an error relative to a target phase shift value). Accordingly, systems 100 may be configured with phase error detection and phase error correction circuits. However, some phase error detection circuits may be associated with relatively complex logic occupying a relatively large area and consuming relatively high power.

In accordance with one or more techniques described herein, phase detection circuits may be implemented that compare a reduced quantity of clock signals (e.g., two clock signals) to increase power efficiency of a system 100. In some examples, the system 100 may include various phase detection circuits that are configured compare multiple clock signals to output (e.g., generate, feedback) one or more phase errors to one or more phase adjustor circuits. In some examples, the phase detector circuits may utilize multiple sets of transistor circuitry (e.g., switching circuitry) to compare the clock signals. The transistor circuitry may be operable based on the multiple clock signals (e.g., or inverted versions thereof, or other clock signals generated based on the multiple clock signals) received from the phase adjustor circuitry. That transistor circuitry may be configured to compensate for a timing difference induced based on reducing the quantity of input clock signals. The phase detector circuit may compare various voltage levels at respective outputs to detect (e.g., identity, determine) one or more phase errors. Accordingly, a phase detector circuit may be configured to detect phase errors based on relatively fewer input clock signals (e.g., and configured to compensate for a timing difference induced by using relatively fewer clock signals), which may reduce semiconductor die area and reduce power consumption of the system 100.

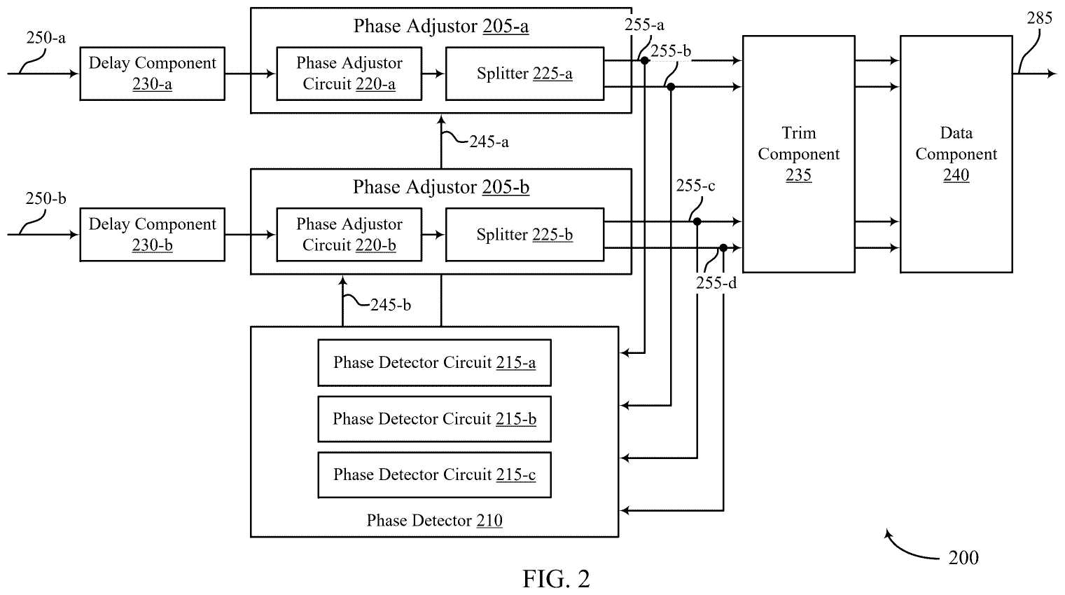

FIG. 2 shows an example of a system 200 that supports phase error detection and correction in accordance with examples as disclosed herein. The system 200 (e.g., a semiconductor system) may be associated with (e.g., included in) the system 100. For example, the host system 105, the memory system 110, or both may include one or more aspects of the system 200. The system 200 may include one or more inputs 250 and one or more outputs 285. That is, although the system 200 shows a non-limiting examples of an input 250-a, an input 250-b, and an output 285, the system 200 may be configured with any quantity of inputs 250 and outputs 285.

The inputs 250 may be associated with respective signals (e.g., clock signals, data signals, command signals). The input 250-a may be associated with non-shifted signal (e.g., a 0 degree phase-shifted signal, a baseline signal), and the input 250-b may be associated with a shifted version (e.g., a 90 degree phase-shifted signal, relative to the signal at the input 250-a) of the signal at the input 250-a. Each of the signals may pass through respective delay components 230 (e.g., delay lines, a delay component 230-a, a delay component 230-b), respective phase adjustors 205 (e.g., phase correction components), a trim component 235, and a data component 240 (e.g., a DQ component) along a forward path of the system 200. The system 200 may also include a phase detector 210, which may provide feedback from respective outputs of the phase adjustors 205 back to an input of each respective phase adjustor 205.

The delay components 230 may induce a delay into each signal on its respective path. Each signal may then be input to a respective phase adjustor 205. Each phase adjustor 205 may include a phase adjustor circuit 220 and a splitter 225 (e.g., a signal splitter). A phase adjustor circuit may induce a phase into the signal and the splitter 225 may generate multiple signals 255 (e.g., adjusted signals, adjusted clock signals). For instance, a phase adjustor circuit 220-a (e.g., along a 0 degree phase-shifted signal path) may induce a phase into the signal, and the splitter 225-a may generate a first signal 255-a (e.g., 0 degree signal, an unphased signal) and a second signal 255-b (e.g., a 180 degree signal relative to the signal 255-a). A phase circuit 220-b (e.g., along a 90 degree phase-shifted signal path) may induce a phase into the signal, and the splitter 225-b may generate a third signal 255-c (e.g., 90 degree signal relative to the signal 255-a) and a fourth signal 255-d (e.g., a 270 degree signal relative to the signal 255-a).

The signals 255 may be output to the trim component 235, which may adjust the signals 255 in accordance with one or more expected operating characteristics (e.g., timing, shift, voltage) for the data component 240. That is, the trim component 235 may be configured to receive the signal 255-a, the signal 255-b, the signal 255-c, and the signal 255-d and generate one or more output signals (e.g., output clock signals) that are compatible with accessing one or more memory arrays (e.g., of a semiconductor system). The data component 240 may then utilize the signals 255 to perform operations (e.g., such as memory access, reading, writing) based on the signals received at the inputs 250 and generating a corresponding signal (e.g., a memory access signal, a DQ signal) at the output 285. That is, the data component 240 may receive the one or more output signals from the trim component and output a data signal at the output 285, and the data signal may be associated with accessing one or more memory arrays. However, in some cases, one or more phase errors may be induced along the respective signal paths between the input 250 and the trim component 235. Such errors may result in malfunction of the data component 240, which may degrade data access speeds and reduce efficiency of the system 200. Thus, the system may include the phase detector 210 to detect such phase errors between the signals 255. The phase detector 210 may include outputs 245 that are configured to transmit feedback (e.g., an indication of one or more phase errors) to the respective phase adjustors 205 such that the phase adjustors 205 may correct any phase errors induced along the signal path.

In some cases, the phase detector 210 may include various phase detector circuits 215 to detect a set of multiple phase errors (e.g., four phase skew) based on various signals 255 (e.g., phased signals, clock signals, adjusted clock signals) output by the phase adjustor 205-a and the phase adjustor 205-b. Each phase detector circuit 215 may compare respective signals 255. For instance, in some cases (e.g., for four phase error correction), a phase detector circuit 215-a (e.g., a 0-90-180-270 phase detector) may be configured to detect a phase error based on receiving and comparing the signal 255-a (e.g., 0 degree), the signal 255-b (e.g., 180 degree), the signal 255-c (e.g., 90 degree), and the signal 255-d (e.g., 270 degree). The phase detector circuit 215-b (e.g., a 0-180 phase detector) may be configured to detect a phase error based on the signal 255-a (e.g., 0 degree) and the signal 255-b (e.g., 180 degree). The phase detector circuit 215-c may be configured to detect a phase error based on the signal 255-c (e.g., 90 degree) and the signal 255-d (e.g., 270 degree).

Accordingly, based on each of the phase detection circuits 215, a phase between each of the signals 255 may be detected and indicated to the phase adjustors 205 via the outputs 245 (e.g., an output 245-a for the phase adjustor 205-a and an output 245-b for the phase adjustor 205-b) for correction. That is, the phase detector 210 may include one or more outputs 245 coupled with the phase adjustor 205-a and the phase adjustor 205-b, and the one or more outputs 245 may be configured to transmit one or more phase errors based on the phase detector circuit 215-a, the phase detector circuit 215-b, and the phase detector circuit 215-c. However, some phase detectors 210 (e.g., some phase detector circuits 215) may be associated with relatively complex logic (e.g., complex circuit architecture), which may increase area utilization and power consumption. For instance, a phase detector that compares each of the signals 255 (e.g., a 0-90-180-270 phase detector) may measure a respective phase between each of the signals 255 and may utilize relatively complex logic to perform the comparison.

In accordance with one or more aspects described herein, a phase detector 210 and its phase detector circuits 215 may be improved (e.g., with updated topology) to reduce complexity and reduce power consumption. In some examples, a phase detector 210 may implement a phase detector circuit 215 that is configured to compare relatively fewer signals 255 (e.g., a 0-90-180-270 phase detector circuit may be replaced by a 0-90 phase detector circuit), or different signals 255 (e.g., a 90-270 phase detector circuit may be replaced by a 0-270 phase detector circuit), while detecting a same phase error. Reducing a quantity or changing the signals 255 for comparison at a phase detector circuit 215 may result in lost timing information (e.g., may induce a timing difference between the compared signals). To compensate for the lost timing information, a phase detector circuit (e.g., a 0-90 phase detector) may utilize various transistor circuits. For example, the transistor circuits may be controlled based on applying respective signals 255 (e.g., or modified versions thereof) to gates of multiple sets of transistors.

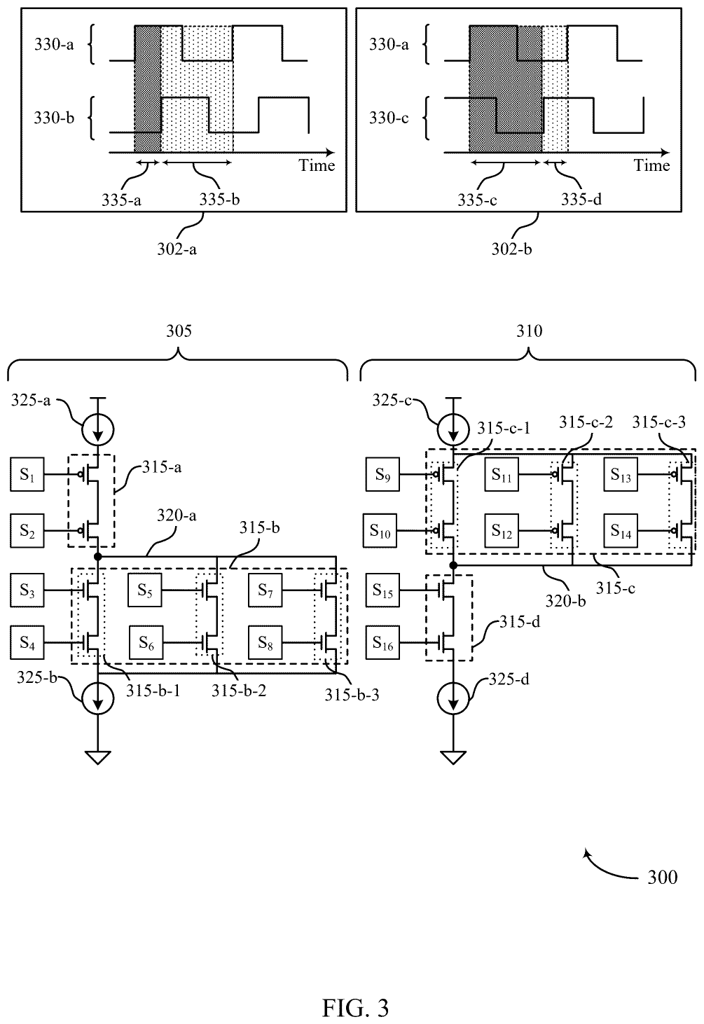

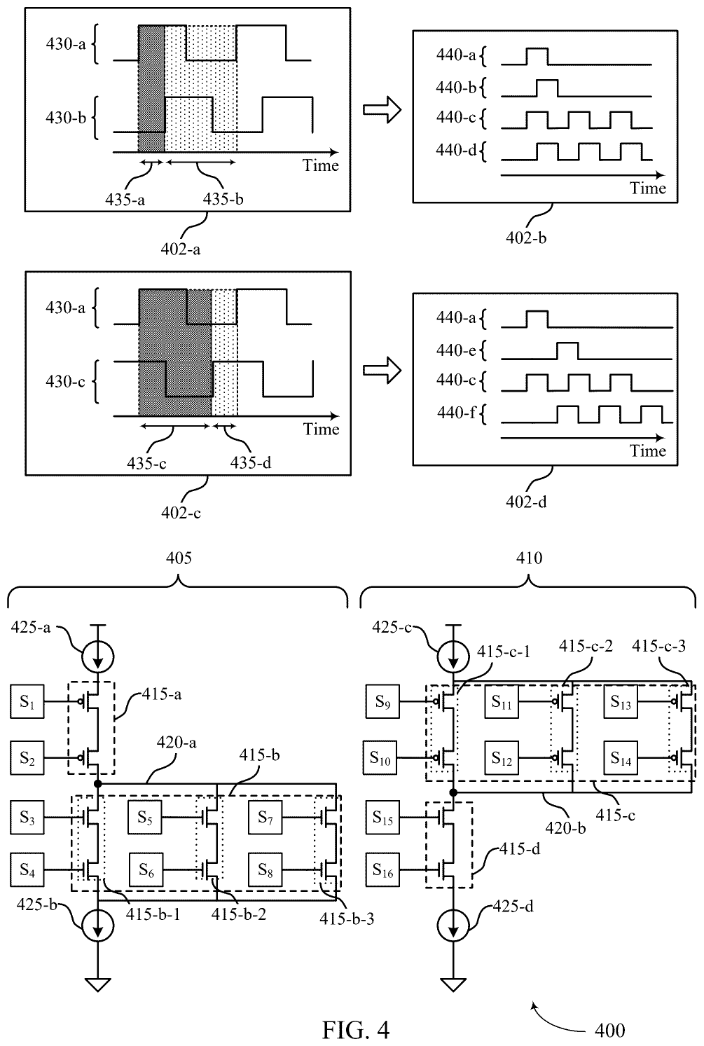

In some examples, the multiple sets of transistors may be coupled between various current sources that are associated with various current levels, which may enable the phase detector circuit 215 to compensate for the lost time information. Such examples may be described in greater detail herein, including with reference to FIG. 3. Additionally, or alternatively, the multiple sets of transistors may be controlled based on respective quantities of signal pulses (e.g., that activate or deactivate respective transistors) that compensate for the lost time information, which may be described in greater detail herein, including with reference to FIG. 4. In some examples, the phase adjustor 205-a may be configured to receive a first input clock signal (e.g., via the input 250-a) and a first indication of a first phase error (e.g., via the output 245-a). The phase adjustor 205-a may be configured to generate a signal 255-a and a signal 255-b based on the first input clock signal and the first phase error. The phase adjustor 205-b may be configured to receive a second input clock signal (e.g., via the input 250-b) and a second indication of a second phase error (e.g., via the output 245-b). The second input clock signal may be shifted in phase relative to the first input clock signal (e.g., by 90 degrees). The phase adjustor 205-b may generate a signal 255-c and a signal 255-d based on the second input clock signal and the second phase error.

In some examples, the phase detector circuit 215-a may be configured to compare the signal 255-a to the signal 255-c (e.g., 0-90 phase detector), the phase detector circuit 215-b may be configured to compare the signal 255-a to the signal 255-b (e.g., 0-180 phase detector), and the phase detector circuit 215-c may be configured to compare the signal 255-c to the signal 255-d (e.g., 90-270 phase detector). Alternatively, the phase detector circuit 215-c may be configured to compare the signal 255-a to the signal 255-d (e.g., 0-270 phase detector), and thus, each of the phase detector circuits 215 may perform a comparison with a common signal 255 (e.g., the signal 255-a, using 0 degree signal as a reference signal).

The phase detector circuit 215-a may be configured to generate a first voltage level based on the signal 255-a and the signal 255-c (e.g., or respective inversions thereof) being applied to one or more first transistor gates of the phase detector circuit 215-a and generate a second voltage level based on the signal 255-a and the signal 255-c being applied to one or more second transistor gates of the phase detector circuit 215-a. The phase detector circuit 215-a may compare the first voltage level to the second voltage level, and a first phase error and a second phase error may be generated based on comparing the first voltage level to the second voltage level.

Additionally, the phase detector circuit 215-c may be configured to generate a first voltage level based on the signal 255-a and the signal 255-d being applied to one or more first transistor gates of the phase detector circuit 215-c. The phase detector circuit 215-c may generate a second voltage level based on the signal 255-a and the signal 255-d being applied to one or more second transistor gates of the phase detector circuit 215-c. The phase detector circuit 215-c may then compare the first voltage level to the second voltage level, and a first phase error and a second phase error may be based on comparing the first voltage level to the second voltage level.

FIG. 3 shows an example of a circuit 300 that supports phase error detection and correction in accordance with examples as disclosed herein. The circuit 300 (e.g., an apparatus, a semiconductor circuit) may be an example of a phase detection circuit 215 as described with reference to FIG. 2 (e.g., a 0-90 phase detector, a 0-270 phase detector). The circuit 300 may include a circuit 305 (e.g., a first circuit portion), a circuit 310 (e.g., a second circuit portion), multiple sets of transistors 315 (e.g., switching components, selection components), multiple outputs 320, and multiple current sources 325. A gate for each transistor of the sets of transistors 315 may be coupled with a respective signal source S_{N} (e.g., S₁, S₂, S₃, S₄, and so on).

FIG. 3 may also show example timing diagrams 302, which may include various signals 330 (e.g., signals 255) that may be input to the circuit 300. That is, the signals 330 may be an example of signals that are to be compared by the circuit 300 to detect one or more phase errors between the signals 330. The timing diagram 302-a may illustrate a first example in which a signal 330-a (e.g., a 0 degree shifted signal) is compared with a signal 330-b (e.g., a 90 degree shifted signal). The timing diagram 302-b may illustrate a second example in which the signal 330-a (e.g., the 0 degree signal) is compared with a signal 330-c (e.g., a 270 degree shifted signal). In some cases, a direct phase comparison between the signal 330-a and the signal 430-b, or between the signal 330-a and the signal 330-c, may not accurately detect a phase error (e.g., in four phase error detection, without losing phase timing information) due to a timing difference (e.g., due to using two signals 330 to detect phase errors instead of three or more signals 330).

In accordance with one or more aspects described herein, the circuit 300 may be configured to compensate for the timing difference (e.g., using a 3-to-1 current source ratio for the circuit 305 and a 1-to-3 current source ratio for the circuit 310) and generate a phase error based on a reduced quantity of input signals (e.g., two signals 330). The circuit 305 (e.g., a first subcircuit) may include a set of transistors 315-a. The set of transistors 315-a may be coupled with a current source 325-a. The circuit 305 may also include a set of transistors 315-b, which may be coupled with a current source 325-b. The set of transistors 315-a and the set of transistors 315-b may be coupled with an output 320-a of the circuit 305 and may be configured to generate a first voltage level at the output 320-a. In some examples, generating the first voltage level at the output 320-a may be based on a set of signals (e.g., clock signals) S₁ through S₈, which may be respectively applied to each gate of the set of transistors 315-a the set of transistors 315-b. In some examples, the current source 325-a may be associated with a greater current level (e.g., three times the current level, by a factor that proportionally compensates for the timing offset) than the current source 325-b.

The circuit 310 may include a set of transistors 315-c, which may be coupled with a current source 325-c. The circuit 310 may also include a set of transistors 315-d, which may be coupled with a current source 325-d. The set of transistors 315-c and the set of transistors 315-d may be coupled with an output 320-b of the circuit 310 and may be configured to generate a second voltage level at the output 320-b of the circuit 310. In some examples, generating the second voltage level at the output 320-b may be based on a set of signals (e.g., clock signals) S₉ through S₁₆, which may be respectively applied to each gate of the set of transistors 315-c and the set of transistors 315-d. In some examples, the current source 325-d may be associated with a greater current level (e.g., three times the current level, by a factor that proportionally compensates for the timing offset) than the current source 325-c.

In some examples, the set of transistors 315-a may include at least two transistors that are coupled in series between the current source 325-a and the output 320-a of the circuit 305. That is a respective channel portion of each transistor of the set of transistors 315-a may be serially coupled between the current source 325-a and the output 320-a. In some examples, the set of transistors 315-a may include P-type (e.g., active low) transistors. A signal S₁ may be applied to a first transistor of the set of transistors 315-a and a signal S₂ may be applied to a second transistor of the set of transistors 315-a. The set of transistors 315-b may include multiple subsets of at least two transistors. For example, the set of transistors 315-b may include a subset of transistors 315-b-1, a subset of transistors 315-b-2, and a subset of transistors 315-b-3. The subsets of transistors 315-b-1, 315-b-2, and 315-b-3 may be coupled in parallel with each other (e.g., may be commonly coupled between the output 320-a and the current source 325-b). The respective transistors of each subset 315-b-1, 315-b-2, and 315-b-3 may be coupled in series between the output 320-a of the circuit 305 and the current source 325-b. A respective signal S_{N} (e.g., S₃ through S₈) of the signals may be applied to each gate of the set of transistors 315-b. In some examples, the set of transistors 315-b may include N-type (e.g., active high) transistors.

Additionally, the set of transistors 315-c may include multiple subsets of at least two transistors. For example, the set of transistors 315-c may include a subset of transistors 315-c-1, a subset of transistors 315-c-2, and a subset of transistors 315-c-3. The subsets of transistors 315-c-1, 315-c-2, and 315-c-3 may be coupled in parallel with each other (e.g., may be commonly coupled between the output 320-b and the current source 325-d). The respective transistors of each subset 315-c-1, 315-c-2, and 315-c-3 may be coupled in series between the output 320-b of the circuit 310 and the current source 325-c. A respective signal S_{N} (e.g., S₉ through S₁₆) may be applied to each gate of the set of transistors 315-c. In some examples, the set of transistors 315-c may include P-type (e.g., active low) transistors. The set of transistors 315-d may include at least two transistors that are coupled in series between the output 320-b of the circuit 310 and the current source 325-d. A signal S₁₅ may be applied to a first transistor of the set of transistors 315-d and a signal S₁₆ may be applied to a second transistors of the set of transistors 315-c. In some examples, the set of transistors 315-d may include N-type (e.g., active high) transistors.

During respective durations, the transistors of the sets of transistors 315 may be individually activated and deactivated such that charge is sourced to and drained from the outputs 320. The activation of each transistor may be based on the signals S_{N} applied to each respective gate. The signals S_{N} may be based on the input signals 330 to the circuit 300. For example, a signal S_{N} may be a same signal as a signal 330 or an inverted version of a signal 330. In some examples, a first voltage level may be generated at the output 320-a based on a first charge that is sourced to the output 320-a of the circuit 305 by the current source 325-a during a first duration (e.g., a duration 335-a, a duration 335-d). Subsequently, a second charge may be drained from the output 320-a of the circuit 305 by the current source 325-b during a second duration (e.g., a duration 335-b, a duration 335-c) that is greater than the first duration. The second voltage level may generated at the output 320-b based on a third charge that is sourced to the output 320-b of the circuit 310 by the current source 325-c during the second duration (e.g., the duration 335-b, the duration 335-c). Subsequently, a fourth charge may be drained from the output 320-b of the circuit 310 by the current source 325-d during the first duration (e.g., the duration 335-a, the duration 335-d).

The circuit 300 may compare the first voltage level generated (e.g., accumulated) at the output 320-a to the second voltage level generated (e.g., accumulated) at the output 320-b (e.g., a differential comparison). The circuit 300 may subsequently generate a phase error associated with a first input clock signal (e.g., the signal 330-a) to the circuit 300 and a second input clock signal (e.g., the signal 330-b or the signal 330-c) to the circuit 300 based on comparing the first voltage level to the second voltage level. Because the current source 325-a may be greater than the current source 325-b, and the current source 325-d may be greater than the current source 325-c, a time difference between two signals 330 may be compensated. For example, if the first voltage level at the output 320-a is different than (e.g., or not within a threshold of) the second voltage level at the output 320-b, the circuit 300 may have detected a phase error between the input signals (e.g., and a delay of the signal 330-b or the signal 330-c may be reduced). If the first voltage level is equal to (e.g., or with a threshold) the second voltage level, there may be no phase error detected between the input signals 330.

As a non-limiting example, the signal 330-a may be referred to as a “0” signal (e.g., an unphased signal, a reference signal) and the signal 330-b may be referred to as a “90” signal (e.g., a 90 degree phase shifted signal relative to the signal 330-a). An inversion of the 0 signal may be referred to as “0F” and an inversion of the 90 signal may be referred to as “90F.” The signals S₁, S₅, S₇, and S₉, may be a 0F signal; the signals S₂, S₄, S₆, and S₁₄, may be a 90 signal; the signals S₃, S₁₁, S₁₃, and S₁₅, may be a 0 signal; and the signals S₈, S₁₀, and S₁₂, and S₁₆, may be a 90F signal. Accordingly, during a duration 335-a the set of transistors 315-a and the set of transistors 315-d may be activated, which may source charge to the output 320-a and may drain charge from the output 320-b. Subsequently, during a duration 335-b, one or more subsets of the set of transistors 315-b and the set of transistors 315-c may be activated, which may drain charge from the output 320-a and may source charge to the output 320-b. In such an example, the relatively larger current sources 325 (e.g., the current source 325-a and the current source 325-d) may compensate for the different between the duration 335-a and the duration 335-b.

As another non-limiting example, the signal 330-c may be referred to as a “270” signal (e.g., a 270 degree phase shifted signal relative to the signal 330-a). An inversion of the 270 signal may be referred to as “270F.” The signals S₁, S₃, S₅, and S₁₃, may be a 0 signal; the signals S₂, S₆, S₈, and S₁₀, may be a 270F signal; the signals S₄, S₁₂, S₁₄, and S₁₆, may be a 270 signal; and the signals S₇, S₉, and S₁₁, and S₁₅, may be a 90F signal. Accordingly, during a duration 335-c, one or more subsets of the set of transistors 315-b and the set of transistors 315-c may be activated, which may drain charge from the output 320-a and may source charge to the output 320-b. Subsequently, during a duration 335-d the set of transistors 315-a and the set of transistors 315-d may be activated, which may source charge to the output 320-a and may drain charge from the output 320-b. Similarly, the relatively larger current sources 325 (e.g., the current source 325-a and the current source 325-d) may compensate for the difference between the duration 335-c and the duration 335-d.

FIG. 4 shows an example of a circuit 400 that supports phase error detection and correction in accordance with examples as disclosed herein. The circuit 400 (e.g., an apparatus, a semiconductor circuit) may be an example of a phase detection circuit 215 as described with reference to FIG. 2 (e.g., a 0-90 phase detector, a 0-270 phase detector). The circuit 400 may include a circuit 405 (e.g., a first circuit portion), a circuit 410 (e.g., a second circuit portion), multiple sets of transistors 415 (e.g., switching components, selection components), multiple outputs 420, and multiple current sources 425. A gate for each transistor of the sets of transistors 415 may be coupled with a respective signal source S_{N} (e.g., S₁, S₂, S₃, S₄, and so on).

FIG. 4 may also show example timing diagrams 402, which may include various signals 430 (e.g., signals 255) that may be input to the circuit 400. That is, the signals 430 may be an example of signals that are to be compared by the circuit 400 to detect one or more phase errors between the signals 430. The timing diagram 402-a and the timing diagram 402-b may illustrate a first example in which a signal 430-a (e.g., a 0 degree shifted signal) is compared with a signal 430-b (e.g., a 90 degree shifted signal). The timing diagram 402-c and the timing diagram 402-d may illustrate a second example in which the signal 430-a (e.g., the 0 degree signal) is compared with a signal 430-c (e.g., a 270 degree shifted signal). In some cases, a direct phase comparison between the signal 430-a and the signal 430-b, or between the signal 430-a and the signal 430-c, may not accurately detect a phase error (e.g., in four phase error detection, without losing phase timing information) due to a timing difference (e.g., due to using two signals 430 to detect phase errors instead of three or more signals 430).

In accordance with one or more aspects described herein, the circuit 400 may be configured to compensate for the timing difference (e.g., using a 3-to-1 input timing difference and a 1-to-3 input timing difference) and generate a phase error based on a reduced quantity of input signals (e.g., two signals 430). The circuit 405 (e.g., a first subcircuit) may include a set of transistors 415-a. The set of transistors 415-a may be coupled with a current source 425-a. The circuit 405 may also include a set of transistors 415-b, which may be coupled with a current source 425-b. The set of transistors 315-a and the set of transistors 415-b may be coupled with an output 420-a of the circuit 405 and may be configured to generate a first voltage level at the output 420-a of the circuit 405. In some examples, generating the first voltage level at the output 420-a may be based on the signals (e.g., clock signals) S₁ through S₈. A first set of signals (e.g., S₁ and S₂) may be respectively applied to each gate of the set of transistors 415-a, and a second set of signals (e.g., S₃ through S₈) may be respectively applied to the set of transistors 415-b. In some examples, the first set of signals may be associated with a first quantity of clock cycles and the second set of signals may be associated with a second quantity of clock cycles (e.g., different than the first quantity of clock cycles, three times fewer clock cycles). In some examples, the current source 425-a, the current source 425-b, the current source 425-c, and the current source 425-d may be associated with a same current level.

The circuit 410 may include a set of transistors 415-c, which may be coupled with a current source 425-c. The circuit 410 may also include a set of transistors 415-d, which may be coupled with a current source 425-d. The set of transistors 415-c and the set of transistors 315-d may be coupled with an output 420-b of the circuit 410 and may be configured to generate a second voltage level at the output 420-b. In some examples, generating the second voltage level at the output 420-b may be based on the signals (e.g., clock signals S₉ through S₁₆. A third set of signals (e.g., S₉ through S₁₆) may be respectively applied to each gate of the set of transistors 415-c, and a second set of signals (e.g., S₁₅ and S₁₆) may be respectively applied to the set of transistors 415-d. In some examples, the fourth set of signals may be associated with a same quantity of clock cycles as the first set of signals (e.g., applied to the set of transistors 415-a) and the third set of signals may be associated with a same quantity of clock cycles as the second set of signal (e.g., applied to the set of transistors 415-b).

In some examples, the set of transistors 415-a may include at least two transistors that are coupled in series between the current source 425-a and the output 420-a of the circuit 405. That is a respective channel portion of each transistor of the set of transistors 415-a may be serially coupled between the current source 425-a and the output 420-a. In some examples, the set of transistors 415-a may include P-type (e.g., active low) transistors. A signal S₁ may be applied to a first transistor of the set of transistors 415-a and a signal S₂ may be applied to a second transistor of the set of transistors 415-a. The set of transistors 415-b may include multiple subsets of at least two transistors. For example, the set of transistors 415-b may include a subset of transistors 415-b-1, a subset of transistors 415-b-2, and a subset of transistors 415-b-3. The subsets of transistors 415-b-1, 415-b-2, and 415-b-3 may be coupled in parallel with each other (e.g., may be commonly coupled between the output 420-a and the current source 425-b). The respective transistors of each subset 415-b-1, 415-b-2, and 415-b-3 may be coupled in series between the output 420-a of the circuit 405 and the current source 425-b. A respective signal of the second set of signals (e.g., S₃ through S₈) may be applied to each gate of the set of transistors 315-b. In some examples, the set of transistors 315-b may include N-type (e.g., active high) transistors.

Additionally, the set of transistors 415-c may include multiple subsets of at least two transistors. For example, the set of transistors 415-c may include a subset of transistors 415-c-1, a subset of transistors 415-c-2, and a subset of transistors 415-c-3. The subsets of transistors 415-c-1, 415-c-2, and 415-c-3 may be coupled in parallel with each other (e.g., may be commonly coupled between the output 420-b and the current source 425-d). The respective transistors of each subset 415-c-1, 415-c-2, and 415-c-3 may be coupled in series between the output 420-b of the circuit 410 and the current source 425-c. A respective signal of the third set of signals (e.g., S₉ through S₁₆) may be applied to each gate of the set of transistors 415-c. In some examples, the set of transistors 415-c may include P-type (e.g., active low) transistors. The set of transistors 415-d may include at least two transistors that are coupled in series between the output 420-b of the circuit 410 and the current source 425-d. A signal S₁₅ may be applied to a first transistor of the set of transistors 315-d and a signal S₁₆ may be applied to a second transistors of the set of transistors 415-c. In some examples, the set of transistors 415-d may include N-type (e.g., active high) transistors.

The transistors of the sets of transistors 415 may be individually activated and deactivated such that charge is sourced to and drained from the outputs 420. The activation of each transistor may be based on the signals S_{N} applied to each respective gate. The signals S_{N} may be based on a set of signals 440 (e.g., and/or inversions thereof), which may be derived from the input signals 430 to the circuit 400. That is, in order to compensate for a timing difference between a duration 435-a and a duration 435-b, or between the duration 435-c and a duration 435-d, transistors that correspond to the duration 435-a or the duration 435-d (e.g., the set of transistors 415-a and the set of transistors 415-d) may be activated more than transistors corresponding to the duration 435-b or the duration 435-c (e.g., the set of transistors 415-b and the set of transistors 415-c). In some examples, a signal S_{N} may have be a same phase as one of the signals 430, but may have a quantity (e.g., a target quantity, a selected quantity) of clock cycles (e.g., signal pulses, activation pulses) that is different from a corresponding signal 430. For example, a signal 440-a and a signal 440-c may be associated with a same phase as a signal 430-a (e.g., 0 degrees), and the signal 440-a may include one clock cycle and the signal 440-c may include three clock cycles. In some examples, the first quantity of clock cycles may be greater than the second quantity of clock cycles.

In some examples, a first voltage level may be generated at the output 420-a based on a first charge that is sourced to the output 420-a of the circuit 405 by the current source 425-a in accordance with a first quantity of clock cycles (e.g., three clock cycles) associated with the first set of signals applied to the set of transistors 415-a. Subsequently, a second charge may be drained from the output 420-a of the circuit 405 by the current source 425-b during in accordance with a second quantity of clock cycles (e.g., one clock cycle) associated with the second set of signals applied to the set of transistors 415-b. The second voltage level may generated at the output 420-b based on a third charge that is sourced to the output 420-b by the current source 425-c in accordance with the second quantity of clock cycles (e.g., one clock cycle) associated with the third set of signals applied to the set of transistors 415-c. Subsequently, a fourth charge may be drained from the output 420-b of the circuit 410 by the current source 425-d in accordance with the first quantity of clock cycles (e.g., three clock cycles) associated with the fourth set of signals applied to the set of transistors 415-d.

The circuit 400 may compare the first voltage level generated (e.g., accumulated) at the output 420-a to the second voltage level generated (e.g., accumulated) at the output 420-b (e.g., a differential comparison). The circuit 400 may subsequently generate a phase error associated with a first input clock signal (e.g., the signal 430-a) to the circuit 400 and a second input clock signal (e.g., the signal 430-b or the signal 430-c) to the circuit 400 based on comparing the first voltage level to the second voltage level. Because the set of transistors 415-a and the set of transistors 415-d may be activated based on a greater quantity of clock cycles than the set of transistors 415-b and the set of transistors 415-c, a time difference between the signals 430 may be compensated. For example, if the first voltage level at the output 420-a is different than (e.g., or not within a threshold of) the second voltage level at the output 420-b, the circuit 400 may have detected a phase error between the input signals (e.g., and a delay of the signal 430-b or the signal 430-c may be reduced). If the first voltage level is equal to (e.g., or with a threshold) the second voltage level, there may be no phase error detected between the input signals 430.

As a non-limiting example, the signal 430-a may be referred to as a “0” signal (e.g., an unphased signal, a reference signal) and the signal 430-b may be referred to as a “90” signal (e.g., a 90 degree phase shifted signal relative to the signal 430-a). Further, the signal 440-a and the signal 440-c may be referred to as “0S” and “0L” respectively, and inverted versions there may be referred to as “0SF” and “0LF.” The signal 440-b and the signal 440-d may be referred to as “90S” and “90L” respectively (e.g., a 90 degree phase shifted signal), and inverted versions thereof may be referred to as “90SF” and “90LF.” The signal S₁ may be a 0LF signal; the signal S₂ may be a 90L signal; the signals S₃, S₂₂ , and S₁₃ may be a 0S signal; the signals S₄, S₆, and S₁₄ may be a 90S signal; the signals S₅, S₇, and S₉ may be a 0SF signal; the signals S₈, S₁₀, and S₁₂ may be a 90SF signal; the signal S₁₅ may be a 0L signal; and the signal S₁₆ may be a 90LF signal. Accordingly, the set of transistors 415-a and the set of transistors 415-d may be activated in accordance with the signal 440-c and the signal 440-d, which may be associated with a first quantity of clock cycles. Subsequently, one or more subsets of the set of transistors 415-b and the set of transistors 415-c may be activated in accordance with the signal 440-a and the signal 440-b, which may be associated with a second quantity of clock cycles. In such an example, the different quantities of clock cycles may compensate for the difference between the duration 435-a and the duration 435-b.

As another non-limiting example, the signal 440-e and the signal 440-f may be referred to as “270S” and “270L” respectively (e.g., a 270 degree phase shifted signal), and inverted versions thereof may be referred to as “270SF” and “270LF.” The signal S₁ may be a 0L signal; the signal S₂ may be a 270LF signal; the signals S₃, S₅, and S₁₃ may be a 0S signal; the signals S₄, S₁₂, and S₁₄ may be a 270S signal; the signals S₇, S₉, and S₁₁ may be a 0SF signal; the signals S₆, S₈, and S₁₀ may be a 270SF signal; the signal S₁₅ may be a 0LF signal; and the signal S₁₆ may be a 270L signal. Accordingly, the set of transistors 415-a and the set of transistors 415-d may be activated in accordance with the signal 440-c and the signal 440-f, which may be associated with a first quantity of clock cycles. Subsequently, one or more subsets of the set of transistors 415-b and the set of transistors 415-c may be activated in accordance with the signal 440-a and the signal 440-e, which may be associated with a second quantity of clock cycles. In such an example, the different quantities of clock cycles may compensate for the difference between the duration 435-c and the duration 435-d.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 1: A semiconductor system, including: a first phase adjustor configured to: receive a first input clock signal and a first indication of a first phase error; and generate a first adjusted clock signal and a second adjusted clock signal from the first input clock signal based at least in part on the first input clock signal and the first phase error; a second phase adjustor configured to: receive a second input clock signal and a second indication of a second phase error, where the second input clock signal is shifted in phase relative to the first input clock signal; and generate a third adjusted clock signal and a fourth adjusted clock signal from the second input clock signal based at least in part on the second input clock signal and the second phase error; and a phase detector including: a first phase detector circuit configured to compare the first adjusted clock signal to the third adjusted clock signal; a second phase detector circuit configured to compare the first adjusted clock signal to the second adjusted clock signal; a third phase detector circuit configured to compare the first adjusted clock signal or the third adjusted clock signal to the fourth adjusted clock signal; and one or more outputs coupled with the first phase adjustor and the second phase adjustor, the one or more outputs configured to transmit the first phase error and the second phase error based at least in part on the first phase detector circuit, the second phase detector circuit, and the third phase detector circuit.

Aspect 2: The semiconductor system of aspect 1, further including: a trim component configured to: receive the first adjusted clock signal, the second adjusted clock signal, the third adjusted clock signal, and the fourth adjusted clock signal; and generate one or more output clock signals that are compatible with accessing one or more memory arrays of the semiconductor system.

Aspect 3: The semiconductor system of aspect 2, further including: a data component configured to: receive the one or more output clock signals from the trim component; and output a data signal associated with accessing the one or more memory arrays based at least in part on the one or more output clock signals from the trim component.

Aspect 4: The semiconductor system of any of aspects 1 through 3, where: the first phase adjustor includes a first signal splitter circuit that generates the first adjusted clock signal and the second adjusted clock signal; and the second phase adjustor includes a second signal splitter circuit that generates the third adjusted clock signal and the fourth adjusted clock signal.

Aspect 5: The semiconductor system of any of aspects 1 through 4, where the second input clock signal is associated with a 90 degree phase shift relative to the first input clock signal.

Aspect 6: The semiconductor system of any of aspects 1 through 5, where the second adjusted clock signal is associated with a 180 degree phase shift relative to the first adjusted clock signal, the third adjusted clock signal is associated with a 90 degree phase shift relative to the first adjusted clock signal, and the fourth adjusted clock signal is associated with a 270 degree phase shift relative to the first adjusted clock signal.

Aspect 7: The semiconductor system of any of aspects 1 through 6, where the first phase detector circuit is configured to: generate a first voltage level based at least in part on the first adjusted clock signal and the third adjusted clock signal being applied to one or more first transistor gates of the first phase detector circuit; generate a second voltage level based at least in part on the first adjusted clock signal and the third adjusted clock signal being applied to one or more second transistor gates of the first phase detector circuit; and compare the first voltage level to the second voltage level, where the first phase error and the second phase error are based at least in part on comparing the first voltage level to the second voltage level.

Aspect 8: The semiconductor system of any of aspects 1 through 7, where the third phase detector circuit is configured to: generate a first voltage level based at least in part on the first adjusted clock signal and the fourth adjusted clock signal being applied to one or more first transistor gates of the third phase detector circuit; generate a second voltage level based at least in part on the first adjusted clock signal and the fourth adjusted clock signal being applied to one or more second transistor gates of the third phase detector circuit; and compare the first voltage level to the second voltage level, where the first phase error and the second phase error are based at least in part on comparing the first voltage level to the second voltage level.

An apparatus is described. The following provides an overview of aspects of the apparatus as described herein:

Aspect 9: An apparatus, including: a first circuit including a first set of transistors coupled with a first current source and including a second set of transistors coupled with a second current source, where the first set of transistors and the second set of transistors are coupled with an output of the first circuit and are configured to generate a first voltage level at the output of the first circuit based at least in part on a first set of clock signals applied to one or more gates of the first set of transistors and to one or more gates of the second set of transistors, and where the first current source is associated with a greater current level than the second current source; and a second circuit including a third set of transistors coupled with a third current source and including a fourth set of transistors coupled with a fourth current source, where the third set of transistors and the fourth set of transistors are coupled with an output of the second circuit and are configured to generate a second voltage level at the output of the second circuit based at least in part on a second set of clock signals applied to one or more gates of the third set of transistors and to one or more gates of the fourth set of transistors, and where the fourth current source is associated with a greater current level than the third current source.

Aspect 10: The apparatus of aspect 9, where the apparatus is configured to: compare the first voltage level to the second voltage level; and generate a phase error associated with a first input clock signal to the apparatus and a second input clock signal to the apparatus based at least in part on comparing the first voltage level to the second voltage level, where the first set of clock signals and the second set of clock signals are based at least in part on the first input clock signal and the second input clock signal.

Aspect 11: The apparatus of aspect 10, where the second input clock signal is associated with a 90 degree phase shift relative to the first input clock signal.

Aspect 12: The apparatus of any of aspects 10 through 11, where the second input clock signal is associated with a 270 degree phase shift relative to the first input clock signal.

Aspect 13: The apparatus of any of aspects 9 through 12, where: the first set of transistors includes at least two transistors that are coupled in series between the first current source and the output of the first circuit, where a respective clock signal of the first set of clock signals is applied to each gate of the first set of transistors; the second set of transistors includes a first subset of at least two transistors, a second subset of at least two transistors, and a third subset of at least two transistors, the first subset, the second subset, and the third subset being coupled in parallel with each other, where the at least two transistors of the first subset, the second subset, and the third subset are respectively coupled in series between the output of the first circuit and the second current source, and where a respective clock signal of the first set of clock signals is applied to each gate of the second set of transistors; the third set of transistors includes a fourth subset of at least two transistors, a fifth subset of at least two transistors, and a sixth subset of at least two transistors, the fourth subset, the fifth subset, and the sixth subset being coupled in parallel with each other, where the at least two transistors of the fourth subset, the fifth subset, and the sixth subset are respectively coupled in series between the third current source and the output of the second circuit, and where a respective clock signal of the second set of clock signals is applied to each gate of the third set of transistors; and the fourth set of transistors includes at least two transistors that are coupled in series between the output of the second circuit and the fourth current source, where a respective clock signal of the second set of clock signals is applied to each gate of the fourth set of transistors.

Aspect 14: The apparatus of any of aspects 9 through 13, where: the first voltage level is generated based at least in part on a first charge that is sourced to the output of the first circuit by the first current source during a first duration and on a second charge that is drained from the output of the first circuit by the second current source during a second duration, where the second duration is greater than the first duration; and the second voltage level is generated based at least in part on a third charge that is sourced to the output of the second circuit by the third current source during the second duration and on a fourth charge that is drained from the output of the second circuit by the fourth current source during the first duration.

Aspect 15: The apparatus of any of aspects 9 through 14, where: the first set of transistors and the third set of transistors include P-type transistors; and the second set of transistors and the fourth set of transistors include N type transistors.

An apparatus is described. The following provides an overview of aspects of the apparatus as described herein:

Aspect 16: An apparatus, including: a first circuit including a first set of transistors coupled with a first current source, and including a second set of transistors coupled with a second current source, where the first set of transistors and the second set of transistors are coupled with an output of the first circuit and are configured to generate a first voltage level at the output of the first circuit based at least in part on a first set of clock signals applied to one or more gates of the first set of transistors and on a second set of clock signals applied to one or more gates of the second set of transistors, where the first set of clock signals is associated with a first quantity of clock cycles and the second set of clock signals is associated with a second quantity of clock cycles; and a second circuit including a third set of transistors coupled with a third current source and including a fourth set of transistors coupled with a fourth current source, where the third set of transistors and the fourth set of transistors are coupled with an output of the second circuit and are configured to generate a second voltage level at the output of the second circuit based at least in part on a third set of clock signals applied to one or more gates of the third set of transistors and a fourth set of clock signals applied to one or more gates of the fourth set of transistors, where the fourth set of clock signals is associated with the first quantity of clock cycles and the third set of clock signals is associated with the second quantity of clock cycles.

Aspect 17: The apparatus of aspect 16, where the apparatus is configured to: compare the first voltage level to the second voltage level; and generate a phase error associated with a first input clock signal and a second input clock signal to the apparatus based at least in part on comparing the first voltage level to the second voltage level, where the first set of clock signals, the second set of clock signals, the third set of clock signals, and the fourth set of clock signals are based at least in part on the first input clock signal and the second input clock signal.

Aspect 18: The apparatus of aspect 17, where the second input clock signal is associated with a 90 degree phase shift relative to the first input clock signal.

Aspect 19: The apparatus of any of aspects 17 through 18, where the second input clock signal is associated with a 270 degree phase shift relative to the first input clock signal.

Aspect 20: The apparatus of any of aspects 16 through 19, where: the first set of transistors includes at least two transistors that are coupled in series between the first current source and the output of the first circuit, where a respective clock signal of the first set of clock signals is applied to each gate of the first set of transistors; the second set of transistors includes a first subset of at least two transistors, a second subset of at least two transistors, and a third subset of at least two transistors, the first subset, the second subset, and the third subset being coupled in parallel with each other, where the at least two transistors of the first subset, the second subset, and the third subset are respectively coupled in series between the output of the first circuit and the second current source, and where a respective clock signal of the second set of clock signals is applied to each gate of the second set of transistors; the third set of transistors includes a fourth subset of at least two transistors, a fifth subset of at least two transistors, and a sixth subset of at least two transistors, the fourth subset, the fifth subset, and the sixth subset being coupled in parallel with each other, where the at least two transistors of the fourth subset, the fifth subset, and the sixth subset are respectively coupled in series between the third current source and the output of the second circuit, and where a respective clock signal of the third set of clock signals is applied to each gate of the third set of transistors; and the fourth set of transistors includes at least two transistors that are coupled in series between the output of the second circuit and the fourth current source, where a respective clock signal of the fourth set of clock signals is applied to each gate of the fourth set of transistors.

Aspect 21: The apparatus of any of aspects 16 through 20, where: the first voltage level is generated based at least in part on a first charge that is sourced to the output of the first circuit by the first current source in accordance with the first quantity of clock cycles and on a second charge that is drained from the output of the first circuit by the second current source in accordance with the second quantity of clock cycles, where the first quantity of clock cycles is greater than the second quantity of clock cycles; and the second voltage level is generated based at least in part on a third charge that is sourced to the output of the second circuit by the third current source in accordance with the second quantity of clock cycles and on a fourth charge that is drained from the output of the second circuit by the fourth current source in accordance with the first quantity of clock cycles.

Aspect 22: The apparatus of any of aspects 16 through 21, where: the first set of transistors and the third set of transistors are P-type transistors; and the second set of transistors and the fourth set of transistors are N type transistors.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A semiconductor system, comprising:
a first phase adjustor configured to:
receive a first input clock signal and a first indication of a first phase error; and
generate a first adjusted clock signal and a second adjusted clock signal from the first input clock signal based at least in part on the first input clock signal and the first phase error;
a second phase adjustor configured to:
receive a second input clock signal and a second indication of a second phase error, wherein the second input clock signal is shifted in phase relative to the first input clock signal; and
generate a third adjusted clock signal and a fourth adjusted clock signal from the second input clock signal based at least in part on the second input clock signal and the second phase error; and
a phase detector comprising:
a first phase detector circuit configured to compare the first adjusted clock signal to the third adjusted clock signal;
a second phase detector circuit configured to compare the first adjusted clock signal to the second adjusted clock signal;
a third phase detector circuit configured to compare the first adjusted clock signal or the third adjusted clock signal to the fourth adjusted clock signal; and
one or more outputs coupled with the first phase adjustor and the second phase adjustor, the one or more outputs configured to transmit the first phase error and the second phase error based at least in part on the first phase detector circuit, the second phase detector circuit, and the third phase detector circuit.

2. The semiconductor system of claim 1, further comprising:
a trim component configured to:
receive the first adjusted clock signal, the second adjusted clock signal, the third adjusted clock signal, and the fourth adjusted clock signal; and
generate one or more output clock signals that are compatible with accessing one or more memory arrays of the semiconductor system.

3. The semiconductor system of claim 2, further comprising:
a data component configured to:
receive the one or more output clock signals from the trim component; and
output a data signal associated with accessing the one or more memory arrays based at least in part on the one or more output clock signals from the trim component.

4. The semiconductor system of claim 1, wherein:
the first phase adjustor comprises a first signal splitter circuit that generates the first adjusted clock signal and the second adjusted clock signal; and
the second phase adjustor comprises a second signal splitter circuit that generates the third adjusted clock signal and the fourth adjusted clock signal.

5. The semiconductor system of claim 1, wherein the second input clock signal is associated with a 90 degree phase shift relative to the first input clock signal.

6. The semiconductor system of claim 1, wherein the second adjusted clock signal is associated with a 180 degree phase shift relative to the first adjusted clock signal, the third adjusted clock signal is associated with a 90 degree phase shift relative to the first adjusted clock signal, and the fourth adjusted clock signal is associated with a 270 degree phase shift relative to the first adjusted clock signal.

7. The semiconductor system of claim 1, wherein the first phase detector circuit is configured to:
generate a first voltage level based at least in part on the first adjusted clock signal and the third adjusted clock signal being applied to one or more first transistor gates of the first phase detector circuit;
generate a second voltage level based at least in part on the first adjusted clock signal and the third adjusted clock signal being applied to one or more second transistor gates of the first phase detector circuit; and
compare the first voltage level to the second voltage level, wherein the first phase error and the second phase error are based at least in part on comparing the first voltage level to the second voltage level.

8. The semiconductor system of claim 1, wherein the third phase detector circuit is configured to:
generate a first voltage level based at least in part on the first adjusted clock signal and the fourth adjusted clock signal being applied to one or more first transistor gates of the third phase detector circuit;
generate a second voltage level based at least in part on the first adjusted clock signal and the fourth adjusted clock signal being applied to one or more second transistor gates of the third phase detector circuit; and
compare the first voltage level to the second voltage level, wherein the first phase error and the second phase error are based at least in part on comparing the first voltage level to the second voltage level.

9. An apparatus, comprising:
a first circuit comprising a first set of transistors coupled with a first current source and comprising a second set of transistors coupled with a second current source, wherein the first set of transistors and the second set of transistors are coupled with an output of the first circuit and are configured to generate a first voltage level at the output of the first circuit based at least in part on a first set of clock signals applied to one or more gates of the first set of transistors and to one or more gates of the second set of transistors, and wherein the first current source is associated with a greater current level than the second current source; and
a second circuit comprising a third set of transistors coupled with a third current source and comprising a fourth set of transistors coupled with a fourth current source, wherein the third set of transistors and the fourth set of transistors are coupled with an output of the second circuit and are configured to generate a second voltage level at the output of the second circuit based at least in part on a second set of clock signals applied to one or more gates of the third set of transistors and to one or more gates of the fourth set of transistors, and wherein the fourth current source is associated with a greater current level than the third current source.

10. The apparatus of claim 9, wherein the apparatus is configured to:
compare the first voltage level to the second voltage level; and
generate a phase error associated with a first input clock signal to the apparatus and a second input clock signal to the apparatus based at least in part on comparing the first voltage level to the second voltage level, wherein the first set of clock signals and the second set of clock signals are based at least in part on the first input clock signal and the second input clock signal.

11. The apparatus of claim 10, wherein the second input clock signal is associated with a 90 degree phase shift relative to the first input clock signal.

12. The apparatus of claim 10, wherein the second input clock signal is associated with a 270 degree phase shift relative to the first input clock signal.

13. The apparatus of claim 9, wherein:
the first set of transistors comprises at least two transistors that are coupled in series between the first current source and the output of the first circuit, wherein a respective clock signal of the first set of clock signals is applied to each gate of the first set of transistors;
the second set of transistors comprises a first subset of at least two transistors, a second subset of at least two transistors, and a third subset of at least two transistors, the first subset, the second subset, and the third subset being coupled in parallel with each other, wherein the at least two transistors of the first subset, the second subset, and the third subset are respectively coupled in series between the output of the first circuit and the second current source, and wherein a respective clock signal of the first set of clock signals is applied to each gate of the second set of transistors;
the third set of transistors comprises a fourth subset of at least two transistors, a fifth subset of at least two transistors, and a sixth subset of at least two transistors, the fourth subset, the fifth subset, and the sixth subset being coupled in parallel with each other, wherein the at least two transistors of the fourth subset, the fifth subset, and the sixth subset are respectively coupled in series between the third current source and the output of the second circuit, and wherein a respective clock signal of the second set of clock signals is applied to each gate of the third set of transistors; and
the fourth set of transistors comprises at least two transistors that are coupled in series between the output of the second circuit and the fourth current source, wherein a respective clock signal of the second set of clock signals is applied to each gate of the fourth set of transistors.

14. The apparatus of claim 9, wherein:
the first voltage level is generated based at least in part on a first charge that is sourced to the output of the first circuit by the first current source during a first duration and on a second charge that is drained from the output of the first circuit by the second current source during a second duration, wherein the second duration is greater than the first duration; and
the second voltage level is generated based at least in part on a third charge that is sourced to the output of the second circuit by the third current source during the second duration and on a fourth charge that is drained from the output of the second circuit by the fourth current source during the first duration.

15. The apparatus of claim 9, wherein:
the first set of transistors and the third set of transistors comprise P-type transistors; and
the second set of transistors and the fourth set of transistors comprise N type transistors.

16. An apparatus, comprising:
a first circuit comprising a first set of transistors coupled with a first current source, and comprising a second set of transistors coupled with a second current source, wherein the first set of transistors and the second set of transistors are coupled with an output of the first circuit and are configured to generate a first voltage level at the output of the first circuit based at least in part on a first set of clock signals applied to one or more gates of the first set of transistors and on a second set of clock signals applied to one or more gates of the second set of transistors, wherein the first set of clock signals is associated with a first quantity of clock cycles and the second set of clock signals is associated with a second quantity of clock cycles; and
a second circuit comprising a third set of transistors coupled with a third current source and comprising a fourth set of transistors coupled with a fourth current source, wherein the third set of transistors and the fourth set of transistors are coupled with an output of the second circuit and are configured to generate a second voltage level at the output of the second circuit based at least in part on a third set of clock signals applied to one or more gates of the third set of transistors and a fourth set of clock signals applied to one or more gates of the fourth set of transistors, wherein the fourth set of clock signals is associated with the first quantity of clock cycles and the third set of clock signals is associated with the second quantity of clock cycles.

17. The apparatus of claim 16, wherein the apparatus is configured to:
compare the first voltage level to the second voltage level; and
generate a phase error associated with a first input clock signal and a second input clock signal to the apparatus based at least in part on comparing the first voltage level to the second voltage level, wherein the first set of clock signals, the second set of clock signals, the third set of clock signals, and the fourth set of clock signals are based at least in part on the first input clock signal and the second input clock signal.

18. The apparatus of claim 17, wherein the second input clock signal is associated with a 90 degree phase shift relative to the first input clock signal.

19. The apparatus of claim 17, wherein the second input clock signal is associated with a 270 degree phase shift relative to the first input clock signal.

20. The apparatus of claim 16, wherein:
the first set of transistors comprises at least two transistors that are coupled in series between the first current source and the output of the first circuit, wherein a respective clock signal of the first set of clock signals is applied to each gate of the first set of transistors;
the second set of transistors comprises a first subset of at least two transistors, a second subset of at least two transistors, and a third subset of at least two transistors, the first subset, the second subset, and the third subset being coupled in parallel with each other, wherein the at least two transistors of the first subset, the second subset, and the third subset are respectively coupled in series between the output of the first circuit and the second current source, and wherein a respective clock signal of the second set of clock signals is applied to each gate of the second set of transistors;
the third set of transistors comprises a fourth subset of at least two transistors, a fifth subset of at least two transistors, and a sixth subset of at least two transistors, the fourth subset, the fifth subset, and the sixth subset being coupled in parallel with each other, wherein the at least two transistors of the fourth subset, the fifth subset, and the sixth subset are respectively coupled in series between the third current source and the output of the second circuit, and wherein a respective clock signal of the third set of clock signals is applied to each gate of the third set of transistors; and
the fourth set of transistors comprises at least two transistors that are coupled in series between the output of the second circuit and the fourth current source, wherein a respective clock signal of the fourth set of clock signals is applied to each gate of the fourth set of transistors.

21. The apparatus of claim 16, wherein:
the first voltage level is generated based at least in part on a first charge that is sourced to the output of the first circuit by the first current source in accordance with the first quantity of clock cycles and on a second charge that is drained from the output of the first circuit by the second current source in accordance with the second quantity of clock cycles, wherein the first quantity of clock cycles is greater than the second quantity of clock cycles; and
the second voltage level is generated based at least in part on a third charge that is sourced to the output of the second circuit by the third current source in accordance with the second quantity of clock cycles and on a fourth charge that is drained from the output of the second circuit by the fourth current source in accordance with the first quantity of clock cycles.

22. The apparatus of claim 16, wherein:
the first set of transistors and the third set of transistors are P-type transistors; and
the second set of transistors and the fourth set of transistors are N type transistors.
